(19) United States
(12) Patent Application Publication
(10) Pub. No.: US 2025/0191914 A1
(43) Pub. Date: Jun. 12, 2025

(54) MULTILAYERED STRUCTURE, SEMICONDUCTOR DEVICE, AND MANUFACTURING METHOD THEREOF

(71) Applicant: Japan Display Inc., Tokyo (JP)

(72) Inventors: Hayata AOKI, Tokyo (JP); Masumi NISHIMURA, Tokyo (JP)

(73) Assignee: Japan Display Inc., Tokyo (JP)

(21) Appl. No.: 19/059,397

(22) Filed: Feb. 21, 2025

Related U.S. Application Data
(63) Continuation of application No. PCT/JP2023/021903, filed on Jun. 13, 2023.

(30) Foreign Application Priority Data
Sep. 1, 2022 (JP) 2022-139267

(51) Int. Cl. H01L 21/02; H10D 30/47; H10D 62/40; H10D 62/85

(52) U.S. Cl. CPC H01L 21/0254; H01L 21/02428; H01L 21/02494; H10D 62/40; H10D 62/8503; H10D 30/475

(57) ABSTRACT

A multilayered structure includes an amorphous substrate having an insulating surface; an orientation layer having a pattern on the amorphous substrate; and a semiconductor layer comprising a gallium nitride having a pattern on the orientation layer, wherein an angle between a bottom surface and a side surface of the orientation layer is greater than 60° and less than 90°. A width of a cross-section of the orientation layer parallel to a bottom surface of the orientation layer is less than a width of the bottom surface of the orientation layer between the bottom surface of the orientation layer and a top surface of the orientation layer.

### CROSS-REFERENCE TO RELATED APPLICATIONS

This application is a Continuation of International Patent Application No. PCT/JP2023/021903, filed on Jun. 13, 2023, which claims the benefit of priority to Japanese Patent Application No. 2022-139267, filed on Sep. 1, 2022, the entire contents of which are incorporated herein by reference.

### FIELD

An embodiment of the present invention relates to a multilayered structure containing a semiconductor layer having gallium nitride, a semiconductor device using the multilayered structure, and a method for manufacturing the multilayered structure.

### BACKGROUND

In recent years, a semiconductor device using a semiconductor layer (hereinafter referred to as “gallium nitride-based semiconductor layer”) containing gallium nitride (GaN) has been developed. For example, a transistor element such as a HEMT (High Electron Mobility Transistor) and a light-emitting element such as an LED (Light-emitting Diode) are known as the semiconductor device using the gallium nitride-based semiconductor layer. In particular, demand for a light-emitting device using the light-emitting diode (LED) for each pixel is high, and a technique for forming a highly crystalline gallium nitride-based semiconductor layer on a substrate other than a silicon substrate has been rapidly developed. For example, Japanese laid-open patent publication No. 2018-168029 discloses a technique in which a buffer layer is formed on an insulating substrate such as a sapphire substrate or a quartz glass substrate, an insulating pattern is formed on the buffer layer, and the gallium nitride-based semiconductor layer is formed on the buffer layer and the insulating pattern.

### SUMMARY

A multilayered structure according to an embodiment of the present disclosure includes an amorphous substrate having an insulating surface; an orientation layer having a pattern on the amorphous substrate; and a semiconductor layer comprising gallium nitride having a pattern on the orientation layer, wherein an angle between a bottom surface and a side surface of the orientation layer is greater than 60° and less than 90°.

A manufacturing method of a multilayered structure according to an embodiment of the present disclosure includes depositing an orientation film over an amorphous substrate having an insulating surface; forming an orientation layer having a pattern by etching the orientation film; depositing a first semiconductor film comprising gallium nitride on a top surface and a side surface of the orientation layer; and forming a first semiconductor layer by etching the first semiconductor film deposited on the side surface of the orientation layer, wherein an angle between a bottom surface and the side surface of the orientation layer is greater than 60° and less than 90°.

### BRIEF DESCRIPTION OF DRAWINGS

FIG. 1 is an end view showing a method for manufacturing a multilayered structure using a semiconductor layer containing gallium nitride according to the first embodiment of the present invention.

FIG. 2 is an end view showing a method for manufacturing a multilayered structure using a semiconductor layer containing gallium nitride according to the first embodiment of the present invention.

FIG. 3 is an end view showing a method for manufacturing a multilayered structure using a semiconductor layer containing gallium nitride according to the first embodiment of the present invention.

FIG. 4 is an end view showing a method for manufacturing a multilayered structure using a semiconductor layer containing gallium nitride according to the first embodiment of the present invention.

FIG. 5 is an end view showing a method for manufacturing a multilayered structure using a semiconductor layer containing gallium nitride according to the first embodiment of the present invention.

FIG. 6 is an end view showing a method for manufacturing a multilayered structure using a semiconductor layer containing gallium nitride according to the first embodiment of the present invention.

FIG. 7 is an end view showing a semiconductor device having a multilayered structure according to the first embodiment of the present invention.

FIG. 8 is a plan view showing a light emitting device using a semiconductor device containing a multilayered structure according to the first embodiment of the present invention.

FIG. 9 is an end view showing a method for manufacturing a multilayered structure using a semiconductor layer containing gallium nitride according to the first embodiment of the present invention.

FIG. 10 is an end view showing a method for manufacturing a multilayered structure using a semiconductor layer containing gallium nitride according to the first embodiment of the present invention.

FIG. 11 is an end view showing a method for manufacturing a multilayered structure using a semiconductor layer containing gallium nitride according to the first embodiment of the present invention.

FIG. 12 is an end view showing a method for manufacturing a multilayered structure using a semiconductor layer containing gallium nitride according to the first embodiment of the present invention.

FIG. 13 is an end view showing a method for manufacturing a multilayered structure using a semiconductor layer containing gallium nitride according to the first embodiment of the present invention.

FIG. 14 is an end view showing a method for manufacturing a multilayered structure using a semiconductor layer containing gallium nitride according to the first embodiment of the present invention.

FIG. 15 is an end view showing a semiconductor device having a multilayered structure according to a second embodiment of the present invention.

### DESCRIPTION OF EMBODIMENTS

As in the above-described prior art, generally, a gallium nitride-based semiconductor layer is formed by epitaxial growth at a temperature exceeding 1000° C. using a sapphire substrate or a quartz glass substrate having a heat resistance of 1000° C. or higher. However, considering applications to a light-emitting display device, the use of expensive sapphire substrate or quartz glass substrate is problematic in that it hinders the increase in the area of a display screen. In addition, in the processing at a temperature exceeding 1000° C., it takes time to raise the temperature at the start of the processing and to lower the temperature at the end of the processing, and the throughput decreases.

An embodiment of the present invention uses a gallium nitride-based semiconductor layer with high crystallinity on an inexpensive amorphous substrate to form a multilayered structure.

Also, an embodiment of the present invention is to form a multilayered structure with a gallium nitride-based semiconductor layer with high crystallinity at a high throughput.

Hereinafter, embodiments of the present invention will be described with reference to the drawings and the like. However, the present invention can be implemented in various forms without departing from the gist thereof. The present invention is not to be construed as being limited to the description of the embodiments exemplified below. In the drawings, the widths, thicknesses, shapes, and the like of the respective portions may be schematically represented in comparison with actual embodiments for clarity of explanation. However, the drawings are merely examples, and do not limit the interpretation of the present invention.

In describing an embodiment of the present invention, a direction from a substrate toward a semiconductor layer is referred to as “on”, and a reverse direction thereof is referred to as “under”. However, the expression “on” or “under” merely describes the vertical relationship of each element. In addition, the expression “on” or “under” includes not only the case where a third element is interposed between the first element and the second element, but also the case where it is not interposed. Furthermore, the terms “on” or “under” include not only the case where the elements overlap in a plan view, but also the case where they do not overlap.

In describing the embodiments of the present invention, elements having the same functions as those described above may be denoted by the same reference signs or the same reference signs plus letters or other symbols, and descriptions thereof may be omitted. In addition, in the case where a part of an element needs to be described separately, a symbol such as a letter may be attached to a symbol indicating the element to distinguish the element. However, when it is not necessary to distinguish each part of the element, the description will be made using only the reference signs indicating the element.

In describing embodiments of the present invention, expressions such as “α includes A, B, or C,” “α includes any of A, B, and C,” and “a includes one selected from a group consisting of A, B, and C” do not exclude the case where α includes a plurality of combinations of A to C unless otherwise specified. Furthermore, these expressions do not exclude the case where α includes other elements.

### First Embodiment

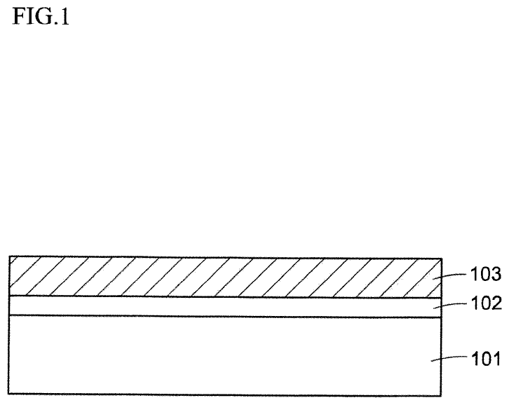

FIG. 1 to FIG. 6 are end views showing methods for manufacturing a multilayered structure having a semiconductor layer containing gallium nitride according to a first embodiment. In particular, FIG. 1 to FIG. 6 show examples of forming a semiconductor layer containing gallium nitride having a pattern on an amorphous substrate. In addition, FIG. 1 to FIG. 6 show an example in which a single semiconductor is formed, but in practice, a plurality of semiconductors is formed on the substrate.

First, as shown in FIG. 1, a base film 102 is formed on an amorphous substrate 101. For example, a glass substrate can be used as the amorphous substrate 101. The glass substrate preferably has a low content of alkaline components, a low thermal expansion coefficient, a high strain point, and a high surface flatness. For example, the content of the alkali metal (such as sodium) is 0.1% or less, the thermal expansion coefficient is lower than 50×10⁻⁷/° C., and the strain point is preferably 600° C. or higher. As will be described later, in the present embodiment, since the gallium nitride-based semiconductor film is formed by a sputtering method, a glass substrate having lower heat resistance than that of a sapphire substrate or quartz substrate can be used. Such a glass substrate is cheaper than the sapphire substrate and the quartz substrate, and is also suitable for increasing the area of the mother glass. However, the amorphous substrate 101 of the present embodiment is not limited to the glass substrate, and may be a resin substrate such as a polyimide substrate, an acryl substrate, a siloxane substrate, or a fluororesin substrate.

The base film 102 serves as a protective film that prevents an impurity from entering from the amorphous substrate 101. For example, the base film 102 is composed of one or more films selected from a silicon nitride film, a silicon oxide film, an aluminum nitride film, and an aluminum oxide film.

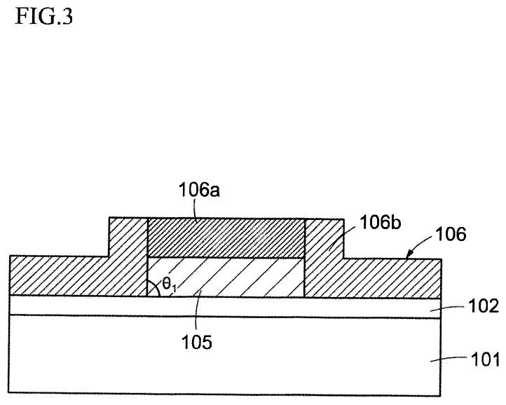

An orientation film 103 is formed on the base film 102. The orientation film 103 has the function of improving the orientation of the crystal of a semiconductor film 106 containing gallium nitride when forming the semiconductor film 106 containing gallium nitride (see FIG. 3), which will be described later.

The orientation film 103 may be conductive or insulating, but preferably has crystallinity oriented along a specific axis (for example, the c-axis). The orientation film 103 is preferably a crystal having rotational symmetry. For example, the crystal surface preferably has six-fold rotational symmetry. In addition, the orientation film 103 preferably has a hexagonal close-packed structure, a face-centered cubic structure, or a structure equivalent thereto. In this case, the structure equivalent to the hexagonal close-packed structure or the face-centered cubic structure includes a crystal structure in which the c-axis does not form 90 degrees with respect to the a-axis and the b-axis. The orientation film 103 having the hexagonal close-packed structure or the structure equivalent thereto is preferably oriented in the (001) direction, that is, the c-axis direction, with respect to the amorphous substrate 101. The orientation film 103 having the face-centered cubic structure or the structure equivalent thereto is preferably oriented in the (111) direction with respect to the amorphous substrate 101.

A surface condition of the orientation film 103 affects the crystallinity of the semiconductor film 106 containing gallium nitride, which will be described later, so it is desirable that the surface of the orientation film 103 be flat. For example, the surface of the orientation film 103 should have an arithmetic mean roughness (Ra) of less than 2.3 nm.

The orientation film 103 described above is, for example, a conductive orientation film. For example, conductive orientation films such as titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), and the like can be used. In particular, titanium, graphene, and zinc oxide are preferably used as the conductive orientation film. In the present embodiment, a titanium layer is used as the orientation film 103.

The orientation film 103 described above is, for example, an insulating orientation film. For example, insulating orientation films such as aluminum nitride (AlN), aluminum oxide (Al₂O₃), lithium niobate (LiNbO), BiLaTiO, SrFeO, BiFeO, BaFeO, ZnFeO, PMnN-PZT, biological apatite (BAp), or the like can be used. In particular, aluminum nitride or aluminum oxide is preferably used as the insulating orientation film. In the present embodiment, the aluminum nitride layer is preferably used as the insulating orientation film.

In this specification and the like, the orientation film 103 may be a conductive orientation film or an insulating orientation film. In the case where there is no need to distinguish between the conductive orientation film and the insulating orientation film, the layer is expressed as the orientation film 103.

For example, a thickness of the orientation film 103 is 50 nm or more (preferably, 50 nm or more and 100 nm or less). The orientation film 103 may be formed by any method. For example, the orientation film 103 can be formed by the sputtering method, the CVD method, the vacuum vapor deposition method, the electron beam evaporation method, or other methods.

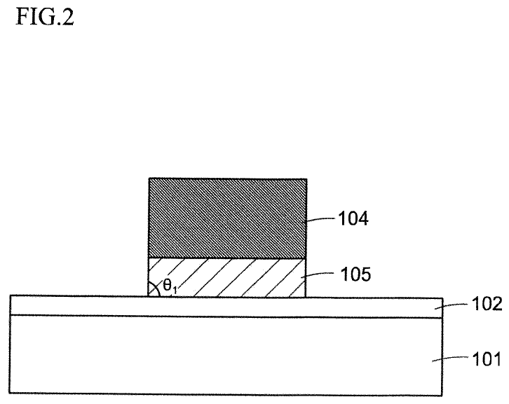

Next, as shown in FIG. 2, an orientation layer 105 having a pattern is formed by etching the orientation film 103 with a resist mask 104. The orientation layer 105 has a gradient (“taper”) where the angle between the bottom surface and the side surface is 01. In the present embodiment, the taper angle θ₁ of the orientation layer 105 can be equal to or greater than 60° and less than or equal to 90° since a dry etching method is used to etch the orientation film 103.

When a wet etching method is used to etch the orientation layer 103, the taper angle θ₁ tends to be small, and depending on the conditions, the taper angle θ₁ is less than 60°. For example, if the taper angle θ₁ of the orientation layer 105 is less than 60°, the area of the taper of the orientation layer 105 is larger than when the angle θ₁ is between 60° and 90°. The semiconductor film 106 containing gallium nitride formed on the taper of the orientation layer 105 tends to have lower crystallinity than the semiconductor film 106 containing gallium nitride formed on the top surface of the orientation layer 105. Therefore, this larger area causes the semiconductor film 106 containing gallium nitride with lower crystallinity to occupy a wider area in the semiconductor film 106 containing gallium nitride.

Furthermore, when a semiconductor film 106 containing gallium nitride with low crystallinity is formed on the taper of the orientation layer 105, the semiconductor film 106 containing gallium nitride with low crystallinity may inhibit crystal growth of the semiconductor film 106 containing gallium nitride deposited on the orientation layer 105. Therefore, in the present embodiment, in order to prevent such crystal growth inhibition, the area of the taper of the orientation layer 105 is suppressed, and in order to suppress the area, a dry etching method is employed so that the taper angle θ₁ of the orientation layer 105 is equal to or greater than 60° and less than or equal to 90°.

Next, as shown in FIG. 3, a semiconductor film 106 containing gallium nitride is formed to cover the orientation layer 105. In the present embodiment, the semiconductor film 106 containing gallium nitride is formed by sputtering as the semiconductor film. Specifically, for example, the semiconductor film 106 containing gallium nitride is formed by the sputtering method in a state where the amorphous substrate 101 having an insulating surface (here, the amorphous substrate 101 in which the base film 102 is arranged) is heated to 25° C. to 600° C., preferably 25° C. to 400° C. In other words, the semiconductor film 106 containing gallium nitride is formed at a temperature equal to or lower than the strain point of the amorphous substrate 101. Although gallium nitride is usually formed by a MOCVD method (Metal Organic Chemical Vapor Deposition), the MOCVD method is not appropriate in view of the heat resistance of the amorphous substrate 101 because the process temperature is high. However, in the present embodiment, the sputtering method can be used to form the semiconductor film 106 containing gallium nitride on the inexpensive amorphous substrate 101.

For example, the semiconductor film 106 containing gallium nitride is formed by performing the sputtering using a sintered body of gallium nitride as a sputtering target and argon (Ar) or a mixed gas of argon (Ar) and nitrogen (N₂) as a sputtering gas. For example, a two-pole sputtering method, a magnetron sputtering method, a dual magnetron sputtering method, an opposing target sputtering method, an ion beam sputtering method, or an inductively coupled plasma (ICP) sputtering method can be applied as the sputtering method.

The conductivity type of the semiconductor film 106 containing gallium nitride may be substantially intrinsic or may have n-type conductivity or p-type conductivity. The gallium nitride layer having n-type conductivity may not contain a dopant for performing valence electron control or may be doped with silicon (Si) or germanium (Ge) as an n-type dopant. The gallium nitride layer having p-type conductivity may be doped with one element selected from magnesium (Mg), zinc (Zn), cadmium (Cd), and beryllium (Be) as a p-type dopant. In the case where the n-type dopant is added to the semiconductor film 106 containing gallium nitride, the carrier concentration is preferably 1×10¹⁸/cm³ or more. In the case where the p-type dopant is added to the semiconductor film 106 containing gallium nitride, the carrier concentration is preferably 5×10¹⁶/cm³ or more. Furthermore, in the case where the semiconductor film 106 containing gallium nitride is substantially intrinsic, zinc (Zn) may be contained as a dopant.

In addition, the semiconductor film 106 may contain one or more elements selected from indium (In), aluminum (Al), and arsenic (As). A bandgap of the semiconductor film 106 containing gallium nitride can be adjusted by these elements.

As described above, in the present embodiment, the semiconductor film 106 containing gallium nitride is formed on the amorphous substrate 101 on which the orientation layer 105 is formed. The crystallinity of the semiconductor film 106 formed on the orientation layer 105 is affected by the orientation axis of the orientation layer 105. For example, in the case where the orientation layer 105 has crystallinity of rotational symmetry or c-axis oriented crystallinity, the semiconductor film 106 containing gallium nitride also has crystallinity of c-axis orientation or (111) orientation. The crystallinity of the semiconductor film 106 containing gallium nitride is preferably monocrystalline, but may be polycrystalline, microcrystalline, or nanocrystalline. The crystal structure of the semiconductor film 106 containing gallium nitride may have a wurtzite structure. The orientation of the semiconductor film 106 is preferably the c-axis orientation or (111) orientation. The semiconductor film 106 may contain an amorphous structure near the interface in contact with the orientation layer 105, but preferably has crystallinity in bulk.

The thickness of the semiconductor film 106 containing gallium nitride is not limited, and may be appropriately set according to the structure of the device. The semiconductor film 106 may have a single-layer structure, or may be a multilayered structure including a plurality of layers having different conductivity types and/or compositions.

As shown in FIG. 3, the semiconductor film 106 containing gallium nitride formed on the orientation layer 105 includes a first portion 106a, which reflects the crystallinity of the orientation layer 105, and a second portion 106b, which is less crystalline than the first portion 106a. The first portion 106a is the portion located above the orientation layer 105. The second portion 106b includes the portion located above the base film 102. In FIG. 3, an example of a taper angle θ₁ of 90° is shown, but when the angle θ₁ is less than 90°, for example, 80°, the second portion 106b also includes the portion located above the side surface (tapered portion) of the orientation layer 105, as described above. In the orientation layer 105, the case where the angle between the bottom and side surfaces is 90° is also included in the taper angle θ₁ for convenience.

The first portion 106a has little inhibition of crystal growth by the second portion 106b because the taper angle θ₁ of the orientation layer 105 is equal to or greater than 60° and equal to or less than 90° and the area of the taper of the orientation layer 105 is suppressed, as described above.

The first portion 106a, which reflects the crystallinity of the orientation layer 105, and the second portion 106b, which is less crystalline than the first portion 106a, can be observed with a transmission electron microscope (TEM: Transmission Electron Microscope) to confirm the difference in crystallinity.

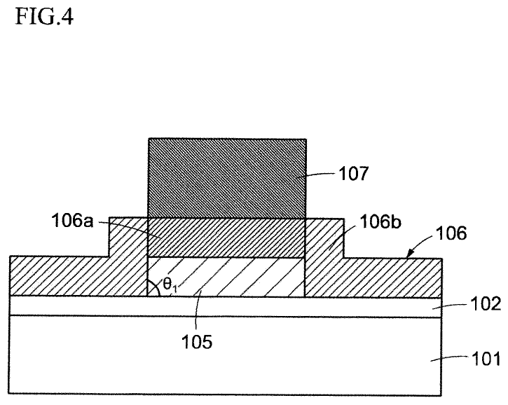

Next, as shown in FIG. 4, a resist mask 107 is formed to superimpose on the first portion 106a of the semiconductor film 106 containing gallium nitride. In other words, the resist mask 107 is arranged to pattern the first portion 106a of the semiconductor film 106 containing gallium nitride, which is located above the top surface of the orientation layer 105. In the present embodiment, the side surface of the first portion 106a and the side surface of the resist mask 107 are shown to coincide, but the width of the resist mask 107 may be narrower or wider than the width of the first portion 106a, and not limited to this example.

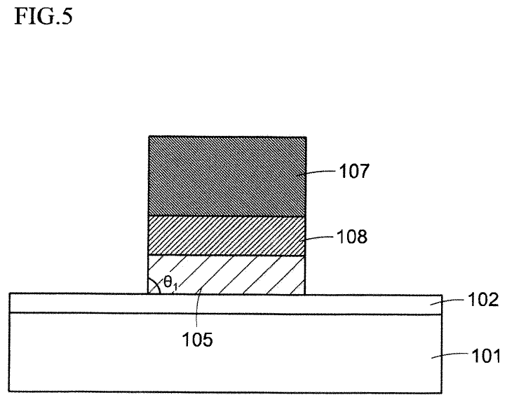

Next, as shown in FIG. 5, etching is performed on the semiconductor film 106 containing gallium nitride using a resist mask 107 to form a semiconductor layer 108 containing gallium nitride having a pattern. In the present embodiment, a dry etching method using halogenated gas is used to etch the semiconductor film 106 containing gallium nitride.

In etching performed on the semiconductor film 106 containing gallium nitride as described above, the etching resistance of the highly crystalline first portion 106a located on the top surface of the orientation layer 105 is higher than that of the second portion 106b. Due to this difference in etching resistance, the width of the semiconductor layer 108 located on the top surface of the orientation layer 105 can be formed without significantly reducing the width of the resist mask 107 by matching the etching conditions to the second portion 106b.

Next, the resist mask 107 is removed. A dry type of resist stripping or a wet type of resist stripping can be used to remove the resist mask 107.

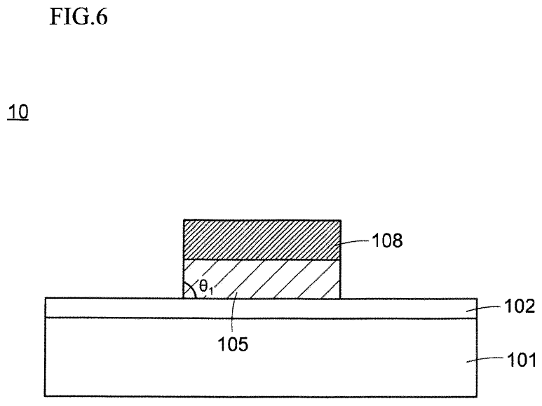

After the above process, the multilayered structure 10 shown in FIG. 6 can be obtained. The semiconductor layer 108 of the multilayered structure 10 in the present embodiment is based on the patterned first portion 106a of the semiconductor film 106 containing gallium nitride, so it has crystallinity aligned with a specific orientation axis, reflecting the orientation of the orientation layer 105. In addition, the first portion 106a formed on the top surface of the orientation layer 105 is less susceptible to crystal growth inhibition by the second portion 106b of the semiconductor film containing gallium nitride with low crystallinity because of the large taper angle of the orientation layer 105. Therefore, the first portion 106a has high etching resistance, and a semiconductor layer 108 containing gallium nitride can be formed that matches the design of the resist mask 107. Therefore, a semiconductor device with excellent characteristics can be realized by processing the multilayered structure 10 having the semiconductor layer 108 of the present embodiment and using it in the semiconductor device.

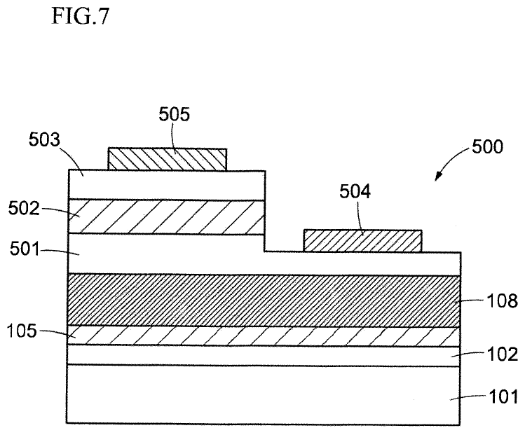

FIG. 7 is an end view of a semiconductor device 500 having the multilayered structure 10 in the first embodiment. Specifically, the semiconductor device 500 shown in FIG. 7 is an example of an LED device manufactured utilizing the multilayered structure 10 shown in FIG. 6. In FIGS. 6 and 7, the relationship between the thicknesses of the orientation layer 105 and the semiconductor layer 108 is different, but for the sake of explanation, the thickness of the orientation layer 105 is only exaggerated in FIG. 6.

Once the semiconductor layer 108 is formed as shown in FIG. 6, an n-type gallium nitride layer 501, a light-emitting layer 502, and a p-type gallium nitride layer 503 are sequentially grown on top of the semiconductor layer 108. Thereafter, parts of the n-type gallium nitride layer 501, the light-emitting layer 502, and the p-type gallium nitride layer 503 are removed so that the n-type gallium nitride layer 501 is exposed. Finally, the n-type electrode 504 and the p-type electrode 505 are formed in contact with the n-type gallium nitride layer 501 and the p-type gallium nitride layer 503, respectively.

Through the above process, the semiconductor device 500 shown in FIG. 7 is completed. The semiconductor device 500 in the present embodiment is formed using the semiconductor layer 108, which uses only the first portion 106a with high crystallinity out of the semiconductor film 106 containing gallium nitride formed on the amorphous substrate 101. Therefore, according to the present embodiment, the semiconductor device 500 can be manufactured on the inexpensive amorphous substrate 101. In addition, according to the present embodiment, since the semiconductor film 106 containing gallium nitride with high crystallinity can be formed by the sputtering method, the semiconductor device 500 can be manufactured with high throughput without being exposed to a high temperature throughout the entire process.

The semiconductor device 500 shown in FIG. 7 is merely an example of an LED element and may be an LED element of another structure. For example, the light-emitting layer 502 may have a quantum-well structure in which the gallium nitride layer and the indium gallium nitride layer are alternately stacked.

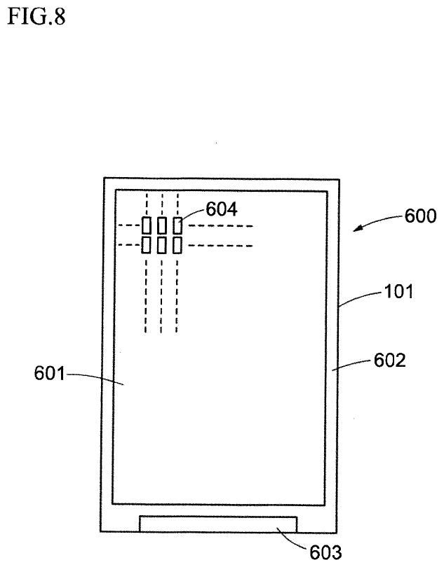

FIG. 8 is a plan view showing a light-emitting device 600 using the semiconductor device 500 including the multilayered structure 10 according to the first embodiment. As shown in FIG. 8, a display unit 601 and a peripheral circuitry 602 are arranged on the amorphous substrate 101. A terminal 603 for inputting various signals (video signals and control signals) to the light-emitting device 600 is arranged in part of the peripheral circuitry 602. A plurality of pixels 604 is arranged in a matrix inside the display unit 601.

In the following, variations of the multilayered structure 10 of the present embodiment will be described. In the figures, the same elements as those of the first embodiment will be marked with the same symbols and duplicated explanations will be omitted.

### <Variation 1>

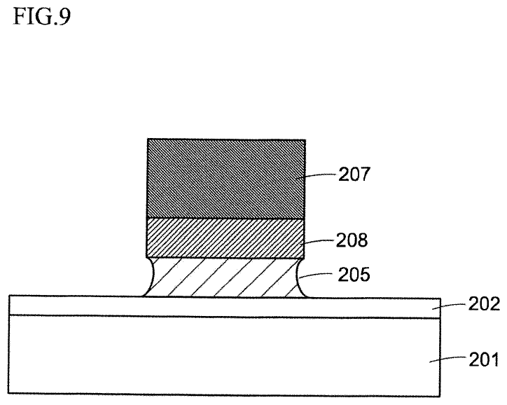

FIG. 9 is an end view of a multilayered structure 20 of an embodiment of the present invention. First, the state shown in FIG. 4 can be obtained according to the process described using FIGS. 1 through 4 of the first embodiment.

Next, as shown in FIG. 9, etching is performed on the semiconductor film containing gallium nitride (semiconductor film 106 containing gallium nitride shown in FIG. 4) using a resist mask 207 to form a semiconductor layer 208 having a pattern. An amorphous substrate 201, a base film 202, a resist mask 207, and an orientation layer 205 shown in FIG. 9 correspond to the amorphous substrate 101, the base film 102, the resist mask 107, and the orientation layer 105, respectively, in FIG. 4.

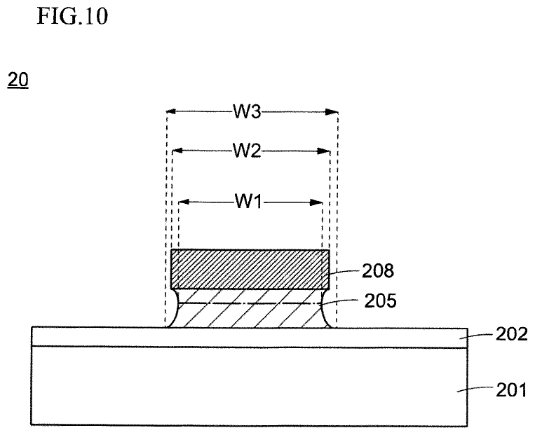

Next, as shown in FIG. 10, the resist mask 207 is removed, and the multilayered structure 20 can be obtained.

As shown in FIG. 9 or FIG. 10, by etching the semiconductor film containing gallium nitride described above, the orientation layer 205 has a width between the top and bottom surfaces that is less than the width of the top surface and the width of the bottom surface.

In detail, as shown in FIG. 10, a width W1 of the cross-section cut in a plane parallel to the bottom surface between the top and bottom surfaces of the orientation layer 205 is less than a width W2 of the bottom surface of the semiconductor layer 208 and also less than a width W3 of the bottom surface of the orientation layer 205. In FIG. 10, an example is shown in which the width W2 of the bottom surface of the semiconductor layer 208 is less than the width W3 of the bottom surface of the orientation layer 205. However, the width W1 of the cross-section cut in a plane parallel to the bottom surface of the orientation layer 205 should be less than the width W2 of the bottom surface of the semiconductor layer 208 and the width W3 of the bottom surface of the orientation layer 205, and the width W2 of the bottom surface of the semiconductor layer 208 may be greater or the same as the width W3 of the bottom surface of the orientation layer 205.

It is possible to etch the semiconductor film containing gallium nitride so as to obtain the shape of the orientation layer 205 shown in FIG. 10, which allows more etching of the less crystalline portions of the semiconductor film. Thereby, it is possible to obtain a semiconductor layer 208 that includes more highly crystalline portions of the semiconductor film. Therefore, a semiconductor device with excellent characteristics can be realized by processing the multilayered structure 20 having the semiconductor layer 208 of the present embodiment and using it in the semiconductor device.

### <Variation 2>

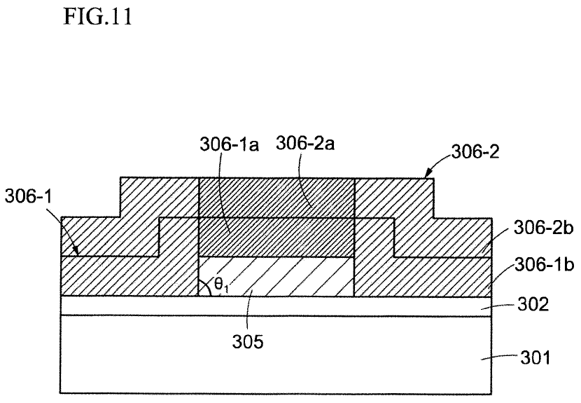

FIG. 11 is an end view of a multilayered structure 30 of one embodiment of the present invention. First, the state shown in FIG. 3 is obtained according to the process described using FIGS. 1 through 3 of the first embodiment.

Next, as shown in FIG. 11, a second semiconductor film 306-2 containing gallium nitride in the same composition ratio as a first semiconductor film 306-1 containing gallium nitride (the semiconductor film 106 containing gallium nitride shown in FIG. 3) is deposited on the first semiconductor film 306-1 containing gallium nitride.

As shown in FIG. 11, the second semiconductor film 306-2 containing gallium nitride formed on the first semiconductor film 306-1 includes a first portion 306-2a and a second portion 306-2b. The first portion 306-2a is located above the first portion 306-1a of the first semiconductor film 306-1, and the second portion 306-2b is located above the first portion 306-1b of the semiconductor film 306-1. Therefore, the crystallinity of the first portion 306-2a is higher than that of the second portion 306-2b. Comparing the crystallinity of the first portion 306-1a of the first semiconductor film 306-1 and the first portion 306-2a of the second semiconductor film 306-2, the crystallinity of the first portion 306-1a of the first semiconductor film 306-1 on the orientation layer 305 is higher.

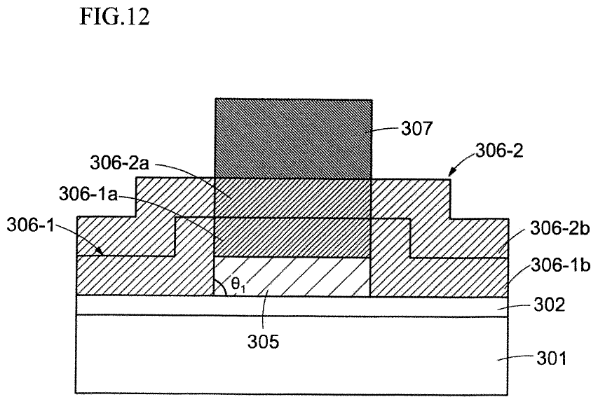

Next, as shown in FIG. 12, a resist mask 307 is formed on the first portion 306-2a of the second semiconductor film 306-2. In FIG. 12, the resist mask 307 is formed with the same width as the first portion 306-2a of the second semiconductor film 306-2, but the width of the resist mask 307 may be wider or narrower than the first portion 306-2a.

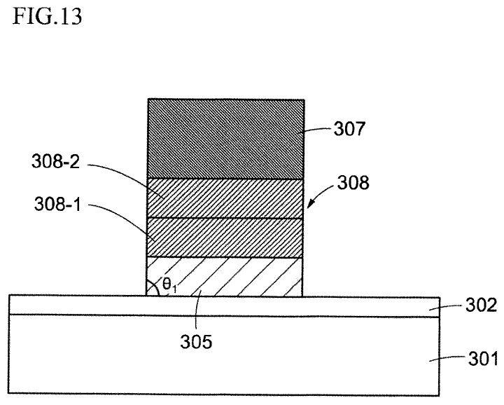

Next, as shown in FIG. 13, by etching the first semiconductor film 306-1 and the second semiconductor film 306-2 successively, a first semiconductor layer 308-1 corresponding to the first portion 306-1a of the first semiconductor film 306-1 and the second semiconductor layer 308-2 corresponding to the first portion 306-2a of the second semiconductor film 306-2 can be formed on the orientation layer 305.

To form the semiconductor layer 308, the second portion 306-1b of the first semiconductor film 306-1 and the second portion 306-2b of the second semiconductor film 306-2 are selectively etched so that the first portion 306-1a and the second portion 306-2a become the semiconductor layer 308 with high crystallinity described above. In addition, the crystallinity of the first portion 306-1a is higher than that of the first portion 306-2a, which tends to provide higher etching resistance for the first portion 306-1a. Therefore, the etching performed during the formation of the semiconductor layer 308 may result in the width of the first semiconductor layer 308-1 corresponding to the etch-resistant first portion 306-1a being greater than the width of the second semiconductor film 308-2 corresponding to the first portion 306-2a. In detail, the width of the bottom surface of the first semiconductor layer 308-1 may be greater than the width of the bottom surface of the second semiconductor layer 308-2.

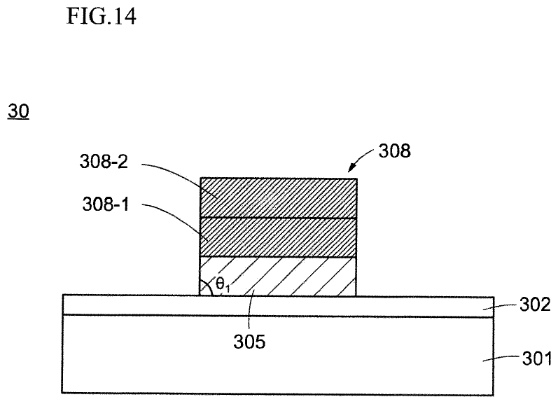

Finally, as shown in FIG. 14, the resist mask 307 is removed, and the multilayered structure 30 is obtained.

As shown in FIG. 14, since the crystallinity of the orientation layer 305 is reflected in the first semiconductor layer 308-1, the second semiconductor layer 308-2 stacked thereon is also highly crystalline, and thus a semiconductor layer 308 with high crystallinity can be obtained with a high thickness. Therefore, by processing the multilayered structure 30 having the semiconductor layer 308 of the present embodiment and using it in a semiconductor device, the semiconductor device with excellent characteristics can be realized.

### Second Embodiment

In the present embodiment, an example in which a semiconductor device is formed having a structure different from that of the first embodiment will be described. Specifically, in the present embodiment, an example in which a HEMT (High Electron Mobility Transistor) is formed as a semiconductor device will be described. In the drawing, the same elements as those shown in the first embodiment are denoted by the same reference signs, and redundant explanations are omitted.

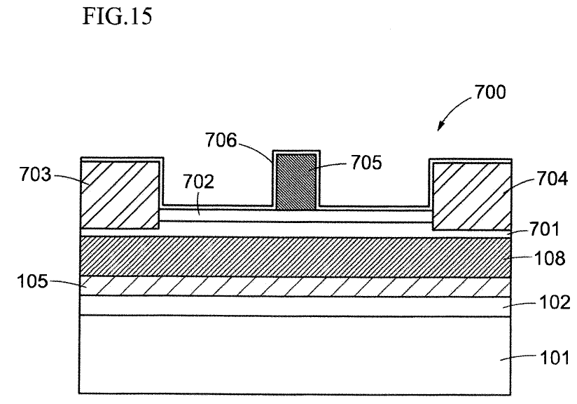

FIG. 15 is an end view showing a semiconductor device 700 including a gallium nitride-based semiconductor layer according to the first embodiment. Specifically, the semiconductor device 700 shown in FIG. 15 is an example of the HEMT manufactured using the semiconductor pattern 111 shown in FIG. 6 in the first embodiment. In FIGS. 6 and 15, the relationship between the thicknesses of the orientation layer 105 and the semiconductor layer 108 is different, but for the sake of explanation, the thickness of the orientation layer 105 is only exaggerated in FIG. 6.

An n-type aluminum gallium nitride layer 701 and an n-type aluminum gallium nitride layer 702 are sequentially formed on top of the semiconductor layer 108, which consists of a gallium nitride layer. The sputtering method can be used to form these gallium nitride-based semiconductor layers. A trench reaching the n-type aluminum gallium nitride layer 701 is arranged in the n-type aluminum gallium nitride layer 701 and the n-type aluminum gallium nitride layer 702, and a source electrode 703 and a drain electrode 704 are arranged therein. A gate electrode 705 in contact with the n-type aluminum gallium nitride layer 702 is arranged between the source electrode 703 and the drain electrode 704. Finally, a silicon nitride layer 706 is formed as a protective layer, thereby completing the HEMT shown in FIG. 15.

The semiconductor device 700 of the present embodiment is formed using the highly crystalline gallium nitride layer (the semiconductor layer 108) formed on the amorphous substrate 101. Therefore, according to the present embodiment, the semiconductor device 700 can be manufactured on the inexpensive amorphous substrate 101. In addition, according to the present embodiment, since a plurality of gallium nitride-based semiconductor layers is formed by a sputtering method, the semiconductor device 700 can be manufactured with high throughput without being exposed to high temperature throughout the entire process. In addition, the semiconductor device 700 shown in FIG. 15 is merely an example of the HEMT, and may be the HEMT of another structure.

Each of the embodiments described above as an embodiment of the present invention can be appropriately combined and implemented as long as no contradiction is caused. The addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

1. A multilayered structure comprising:
an amorphous substrate having an insulating surface;
an orientation layer having a pattern on the amorphous substrate; and
a semiconductor layer comprising gallium nitride having a pattern on the orientation layer,
wherein an angle between a bottom surface and a side surface of the orientation layer is greater than 60° and less than 90°.

2. The multilayered structure according to claim 1,
wherein a width of a cross-section of the orientation layer parallel to the bottom surface of the orientation layer is less than a width of the bottom surface of the orientation layer between the bottom surface of the orientation layer and a top surface of the orientation layer.

3. The multilayered structure according to claim 1,
wherein a width of a cross-section of the orientation layer parallel to the bottom surface of the orientation layer is less than a width of a bottom surface of the semiconductor layer between the bottom surface of the orientation layer and a top surface of the orientation layer.

4. The multilayered structure according to claim 1,
wherein
the semiconductor layer has a first semiconductor layer and a second semiconductor layer on the orientation layer,
a composition ratio of the first semiconductor layer is the same as a composition ratio of the second semiconductor layer, and
a crystallinity of the first semiconductor layer is higher than a crystallinity of the second semiconductor layer.

5. A semiconductor device comprising:
the multilayered structure according to claim 1.

6. A manufacturing method of a multilayered structure comprising:
depositing an orientation film over an amorphous substrate having an insulating surface;
forming an orientation layer having a pattern by etching the orientation film;
depositing a first semiconductor film comprising gallium nitride on a top surface and a side surface of the orientation layer; and
forming a first semiconductor layer by etching the first semiconductor film deposited on the side surface of the orientation layer,
wherein an angle between a bottom surface and the side surface of the orientation layer is greater than 60° and less than 90°.

7. The manufacturing method according to claim 6, further comprising,
depositing a second semiconductor film comprising gallium nitride after depositing the first semiconductor film, and
forming a first semiconductor layer having a pattern on the top surface of the orientation layer and a second semiconductor layer having a pattern on the top surface of the orientation layer by etching the first semiconductor film and the second semiconductor film successively,
wherein a width of a bottom surface of the first semiconductor layer is equal to or more than a width of a bottom surface of the second semiconductor layer.

8. The manufacturing method according to claim 6, further comprising,
etching the orientation layer successively or after forming the first semiconductor layer,
wherein a width of a cross-section of the orientation layer parallel to a bottom surface of the orientation layer is less than a width of the bottom surface of the orientation layer between the bottom surface and a top surface of the orientation layer.

9. A semiconductor device comprising:
the multilayered structure according to claim 2.

10. A semiconductor device comprising:
the multilayered structure according to claim 3.

11. A semiconductor device comprising:
the multilayered structure according to claim 4.
